(19) United States
(12) Patent Application Publication
(10) Pub. No.: US 2025/0183653 A1
(43) Pub. Date: Jun. 5, 2025

(54) ISOLATED SWITCHING CIRCUIT WITH SHORT-CIRCUIT PROTECTION AND METHOD THEREOF

(71) Applicant: Chengdu Monolithic Power Systems Co., Ltd., Chengdu (CN)

(72) Inventors: Yuzhou Zhang, Hangzhou (CN); Pengfei Liu, Hangzhou (CN)

(21) Appl. No.: 18/962,037

(22) Filed: Nov. 27, 2024

(30) Foreign Application Priority Data
Nov. 30, 2023 (CN) 202311639005.4

(51) Int. Cl. H02H 7/12; H02M 3/335

(52) U.S. Cl. CPC H02H 7/1213; H02M 3/33571; H02M 3/33576

(57) ABSTRACT

A control circuit for an asymmetrical half-bridge flyback converter is provided. The control circuit includes a short-circuit indicating circuit and a short-circuit processing circuit. The short-circuit indicating circuit receives an auxiliary winding voltage of a transformer of the asymmetrical half-bridge flyback converter and provides a short-circuit indicating signal based on the auxiliary winding voltage. The short-circuit processing circuit receives the short-circuit indicating signal and provides at least one short-circuit control signal to control the asymmetrical half-bridge flyback converter based on the short-circuit indicating signal. The short-circuit control signal controls the asymmetrical half-bridge flyback converter to stop operating when the short-circuit indicating signal indicates that an output terminal of the asymmetrical half-bridge flyback converter is short-circuited.

### CROSS-REFERENCE TO RELATED APPLICATIONS

This application claims the benefit of and priority to a CN application 202311639005.4, filed on Nov. 30, 2023, which is incorporated herein by reference into the present application.

### TECHNICAL FIELD

The present invention generally relates to electronic circuits, and more particularly but not exclusively to control circuits for isolated switching circuits and associated methods.

### BACKGROUND

As a type of isolated switching circuits, asymmetrical half-bridge flyback converters have several advantages, such as simple structure, high efficiency, requiring fewer components, and low cost. FIG. 1 shows a schematic diagram of a conventional asymmetrical half-bridge flyback converter 10. As shown in FIG. 1, a first switch Q1 and a second switch Q2 are turned on and off alternately in response to a first control signal G1 and a second control signal G2, respectively. Thus, energy could be transferred from an input terminal IN of the asymmetrical half-bridge flyback converter 10 to an output terminal OUT for powering a load Ro.

### SUMMARY

An embodiment of the present invention discloses a control circuit for an asymmetrical half-bridge flyback converter. The asymmetrical half-bridge flyback converter includes a short-circuit indicating circuit and a short-circuit processing circuit. The short-circuit indicating circuit receives an auxiliary winding voltage of a transformer of the asymmetrical half-bridge flyback converter and provides a short-circuit indicating signal based on the auxiliary winding voltage. The short-circuit processing circuit receives the short-circuit indicating signal and provides at least one short-circuit control signal to control the asymmetrical half-bridge flyback converter based on the short-circuit indicating signal. The short-circuit control signal controls the asymmetrical half-bridge flyback converter to stop operating when the short-circuit indicating signal indicates that an output terminal of the asymmetrical half-bridge flyback converter is short-circuited.

Another embodiment of the present invention discloses an asymmetrical half-bridge flyback converter. The asymmetrical half-bridge flyback converter includes a first switch, a second switch, a transformer, a resonant capacitor and a control circuit. The second switch is coupled in series with the first switch between an input terminal of the asymmetrical half-bridge flyback converter and a primary side reference ground. The transformer has a primary winding, a secondary winding and an auxiliary winding. The primary winding is coupled to a switching terminal between the first switch and the second switch. The resonant capacitor is coupled in series with the primary winding of the transformer. The control circuit includes a short-circuit indicating circuit and a short-circuit processing circuit. The short-circuit indicating circuit receives an auxiliary winding voltage of the transformer and provides a short-circuit indicating signal based on the auxiliary winding voltage. The short-circuit processing circuit receives the short-circuit indicating signal and provides a first short-circuit control signal and a second short-circuit control signal based on the short-circuit indicating signal to control the first switch and the second switch respectively. The first switch and the second switch are turned off when the short-circuit indicating signal indicates that an output terminal of the asymmetrical half-bridge flyback converter is short-circuited.

Yet another embodiment of the present invention discloses a method for controlling an isolated switching circuit. The method includes the following steps. An auxiliary winding voltage of a transformer of the isolated switching circuit is sampled and held to obtain an auxiliary winding sampling voltage. A short-circuit indicating signal is provided based on the auxiliary winding sampling voltage. The isolated switching circuit is controlled based on the short-circuit indicating signal. The isolated switching circuit is controlled to stop operating when the short-circuit indicating signal indicates that an output terminal of the isolated switching circuit is short-circuited.

### BRIEF DESCRIPTION OF DRAWINGS

The present invention can be further understood with reference to the following detailed description and the appended drawings, wherein like elements are provided with like reference numerals.

FIG. 1 shows a schematic diagram of a conventional asymmetrical half-bridge flyback converter.

FIG. 2 shows a schematic diagram of an asymmetrical half-bridge flyback converter in accordance with an embodiment of the present invention.

FIG. 3 shows a schematic diagram of a short-circuit indicating circuit in accordance with an embodiment of the present invention.

FIG. 4 shows a schematic diagram of a short-circuit indicating circuit in accordance with an embodiment of the present invention.

FIG. 5 shows a schematic diagram of a short-circuit indicating circuit in accordance with an embodiment of the present invention.

FIG. 6 shows a schematic diagram of a short-circuit indicating circuit in accordance with an embodiment of the present invention.

FIG. 7 shows working waveforms of the asymmetrical half-bridge flyback converter employing the short-circuit indicating circuit shown in FIG. 5 in accordance with an embodiment of the present invention.

FIG. 8 shows a flow diagram of a method for controlling an isolated switching circuit in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Reference to “one embodiment”, “an embodiment”, “an example” or “examples” means: certain features, structures, or characteristics are contained in at least one embodiment of the present invention. These “one embodiment”, “an embodiment”, “an example” and “examples” are not necessarily directed to the same embodiment or example. Furthermore, the features, structures, or characteristics may be combined in one or more embodiments or examples. In addition, it should be noted that the drawings are provided for illustration and are not necessarily to scale. And when an element is described as “connected” or “coupled” to another element, it can be directly connected or coupled to the other element, or there could exist one or more intermediate elements. In contrast, when an element is referred to as “directly connected” or “directly coupled” to another element, there is no intermediate element.

In the asymmetrical half-bridge flyback converter 10, when the output terminal OUT is short-circuited, the output voltage Vout drops, and the voltage across a magnetizing inductance Lm of a transformer T1 also drops. As a result, the resonant current Ir of a primary side flowing in negative direction increases abruptly, and therefore the secondary current Is flowing through a switch Q3 increases and may exceed the rated current of the switch Q3, resulting in damages to the switch Q3. In addition, due to the voltage across the magnetizing inductance Lm of the transformer T1 drops, the demagnetization time of the magnetizing inductance Lm may increase to be longer than the on-time of the second switch Q2. In this case, the switch Q3 may be turned off when the secondary current Is is large. Thus, a large voltage spike is generated across the switch Q3, which damages the switch Q3. It should be appreciated that the short-circuited of the output terminal OUT means that the output terminal OUT is short-circuited to another terminal, e.g., a secondary side reference ground SGND or another output terminal of the asymmetrical half-bridge flyback converter 10.

Therefore, a short-circuit protection is required in the asymmetrical flyback converter 10 to handle the short-circuit of the output terminal OUT in time, to prevent the switch Q3 from being damaged.

Peak current mode control is often adopted in the isolated switching circuit to control energy transfer between the primary side and the secondary side of a transformer. For example, in the asymmetrical half-bridge flyback converter 10 shown in FIG. 1, the peak current mode control refers to when the resonant current Ir of the primary side of the transformer T1 increases to a set peak value, the first switch Q1 is turned off and the second switch Q2 is turned on to transfer the energy from the primary side to the secondary side. In conventional primary side overcurrent protection, the short circuit is determined based on the voltage across a sense resistor Rcs. The voltage across the sense resistor Rcs is generated by the resonant current Ir flowing through the sense resistor Rcs. However, the maximum value of the resonant current Ir of the asymmetrical half-bridge flyback converter 10 is clamped in the peak current mode control. When the first switch Q1 is on and the second switch Q2 is off, the maximum value of the resonant current Ir is the set peak value. Therefore, it is hard to determine whether the short circuit occurs by detecting the resonant current Ir during the on period of the first switch Q1.

On the other hand, when the first switch Q1 is off and the second switch Q2 is on, the resonant current Ir flows in negative direction (i.e., flows from a resonant inductor Lr back to a switching terminal SW shown in FIG. 1) through the sense resistor Rcs to generate the negative voltage across the sense resistor Rcs. Thus, a negative voltage detecting circuit is required to detect the negative voltage, which increases the cost of the detecting circuit. Furthermore, the sense resistor Rcs is coupled in series in a resonant tank, and thus there is energy loss during the operation of the asymmetrical half-bridge flyback converter 10. Therefore, it is undesirable to determine whether the output terminal OUT is short-circuited by detecting the resonant current Ir when the isolated switching circuit employs the peak current mode control.

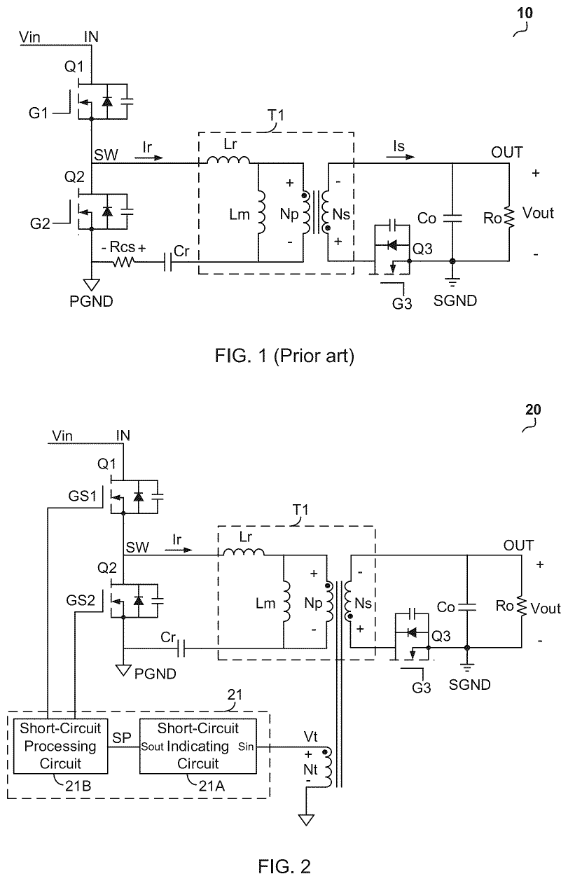

FIG. 2 shows a schematic diagram of an asymmetrical half-bridge flyback converter 20 in accordance with an embodiment of the present invention. The asymmetrical half-bridge flyback converter 20 includes the first switch Q1, the second switch Q2, the transformer T1, a resonant capacitor Cr, the switch Q3 and an output capacitor Co. The first switch Q1 and the second switch Q2 are coupled in series between the input terminal IN and a primary side reference ground PGND. The transformer T1 has a primary winding Np, a secondary winding Ns and an auxiliary winding Nt. The resonant capacitor Cr is coupled in series with the primary winding Np between the switching terminal SW and the primary side reference ground PGND. The switch Q3 is coupled between the secondary winding Ns and the secondary side reference ground SGND. As shown in FIG. 2, the resonant inductor Lr is a leakage inductance of the primary winding Np rather than an actual inductor. In some embodiments, additional discrete inductors may be applied as the resonant inductor Lr according to practical applications. In some applications, the switch Q3 could be coupled between the secondary winding Ns and the output terminal OUT.

In the embodiment of FIG. 2, the energy is transferred from the primary side to the secondary side by alternately turning on and off the first switch Q1 and the second switch Q2, to generate the output voltage Vout across the output capacitor Co and to power the load Ro. Specifically, when the first switch Q1 is on and the second switch Q2 is off, the primary winding Np and the resonant capacitor Cr store energy, and the output capacitor Co powers the load Ro. When the first switch Q1 is off and the second switch Q2 is on, the energy stored in the primary winding Np and the resonant capacitor Cr is transferred to the secondary winding Ns for charging the output capacitor Co and powering the load Ro.

As shown in FIG. 2, a half-bridge circuit formed by the first switch Q1 and the second switch Q2 is coupled between the input terminal IN and the primary side reference ground PGND. The input terminal IN is configured to receive an input voltage Vin. In one embodiment, the input voltage Vin is a DC voltage obtained by rectifying an AC voltage. Ir represents the resonant current flowing through the resonant capacitor Cr. In the embodiment of the present invention, the direction of the resonant current Ir shown in FIG. 2 is assumed to be positive (i.e., from the switching terminal SW to the resonant inductor Lr). A switching voltage Vsw is a voltage of a connection point (i.e., switching terminal SW) between the first switch Q1 and the second switch Q2. In the embodiment of FIG. 2, the first switch Q1 and the second switch Q2 are implemented by MOSFETs (Metal Oxide Semiconductor Field Effect Transistors). In other embodiments, the first switch Q1 and the second switch Q2 may be implemented by other switches, such as BJTs (Bipolar Transistors) and IGBTs (Insulated Gate Bipolar Transistors).

As shown in FIG. 2, the auxiliary winding Nt is magnetically coupled together with the same core of the primary winding Np and the secondary winding Ns. The auxiliary winding Nt is configured to provide an auxiliary winding voltage Vt. The auxiliary winding voltage Vt is determined by the output voltage Vout and the turns ratio of the secondary winding Ns to the auxiliary winding Nt, i.e., Vt:Vout=Nt:Ns. When the turns ratio of the auxiliary winding Nt to the secondary winding Ns is 1:1, the auxiliary winding voltage Vt is equal to the output voltage Vout. In a specific application, the turns ratio of the secondary winding Ns to the auxiliary winding Nt could be set according to the required auxiliary winding voltage Vt.

In the embodiment of FIG. 2, the asymmetrical half-bridge flyback converter 20 includes a control circuit 21. The control circuit 21 includes a short-circuit indicating circuit 21A and a short-circuit processing circuit 21B. The short-circuit indicating circuit 21A has an input terminal Sin configured to receive the auxiliary winding voltage Vt and an output terminal Sout configured to provide a short-circuit indicating signal SP. The short-circuit indicating circuit 21A is configured to determine whether the output terminal OUT is short-circuited based on the auxiliary winding voltage Vt, and to provide the short-circuit indicating signal SP to indicate the short-circuit state.

The short-circuit processing circuit 21B has an input terminal configured to receive the short-circuit indicating signal SP and an output terminal configured to provide a first short-circuit control signal GS1 and a second short-circuit control signal GS2. Based on the short-circuit indicating signal SP, the first short-circuit control signal GS1 is provided to control the first switch Q1 and the second short-circuit control signal GS2 is provided to control the second switch Q2. When the short-circuit indicating signal SP indicates that the output terminal OUT is short-circuited, the short-circuit processing circuit 21B pulls down gates of the first switch Q1 and the second switch Q2 through the first short-circuit control signal GS1 and the second short-circuit control signal GS2, to control the asymmetrical half-bridge flyback converter 20 to stop operating. In other words, the first switch Q1 and the second switch Q2 are turned off when the short-circuit indicating signal SP indicates that the output terminal OUT is short-circuited.

It should be appreciated that the short-circuit processing circuit 21B could provide a single short-circuit control signal to turn off the first switch Q1 and the second switch Q2 simultaneously when the output terminal OUT is short-circuited. In some embodiments, the first short-circuit control signal GS1 is the first control signal G1, the second short-circuit control signal GS2 is the second control signal G2. In other words, the short-circuit processing circuit 21B provides the first control signal G1 to turn off the first switch Q1 and the second control signal G2 to turn off the second switch Q2 when the output terminal OUT is short-circuited. In other embodiments, the isolated switching circuit (e.g., flyback circuit) has a single switch in the primary side, the short-circuit processing circuit 21B provides the single short-circuit control signal to turn off the single switch when the output terminal OUT is short-circuited.

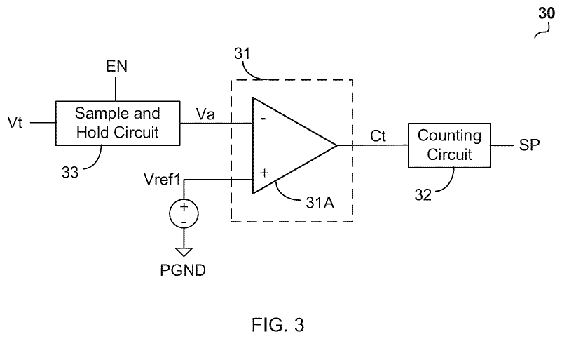

FIG. 3 shows a schematic diagram of a short-circuit indicating circuit 30 in accordance with an embodiment of the present invention. As shown in FIG. 3, the short-circuit indicating circuit 30 includes a voltage detecting circuit 31, a counting circuit 32 and a sample and hold circuit 33. The sample and hold circuit 33 is configured to receive the auxiliary winding voltage Vt and an enable signal EN. Under the control of the enable signal EN, the sample and hold circuit 33 is configured to provide an auxiliary winding sampling voltage Va based on the auxiliary winding voltage Vt. It should be appreciated that the auxiliary winding voltage Vt is associated with the output voltage Vout when the switch Q3 is on, the auxiliary winding voltage Vt may be not associated with the output voltage Vout when the switch Q3 is off.

In the embodiment of FIG. 3, when the switch Q3 is on, the sample and hold circuit 33 is controlled by the enable signal EN to sample the auxiliary winding voltage Vt, thus to provide the auxiliary winding sampling voltage Va based on the auxiliary winding voltage Vt. It should be appreciated that the spike of the output voltage Vout may occur when the switch Q3 turns on or turns off. Therefore, in order to prevent the spike of the output voltage Vout from affecting the sampling of the auxiliary winding voltage Vt, in some embodiments, the enable signal EN is applied to control the sample and hold circuit 33 to sample the auxiliary winding voltage Vt a period of time after the switch Q3 is turned on. The enable signal EN may be implemented by various ways. In one embodiment, the enable signal EN is generated synchronously with a control signal G3 of the switch Q3. In other embodiments, the enable signal EN is generated based on the on and off state of the first switch Q1 or the second switch Q2. The method of sampling the auxiliary winding voltage Vt during the on period of the switch Q3 to obtain information of the output voltage Vout is well-known in the art and descriptions thereof are omitted here.

The voltage detecting circuit 31 includes a comparison circuit 31A. The comparison circuit 31A is configured to receive the auxiliary winding sampling voltage Va and a short-circuit reference voltage Vref1, and to provide a voltage detecting signal Ct based on the comparison result of the auxiliary winding sampling voltage Va and the short-circuit reference voltage Vref1. In one embodiment, the short-circuit reference voltage Vref1 is a constant value which is less than the auxiliary winding sampling voltage Va of the asymmetrical half-bridge flyback converter 20 under normal operation. In one embodiment, the short-circuit reference voltage Vref1 is provided by a voltage source.

The counting circuit 32 is configured to receive the voltage detecting signal Ct, and to provide the short-circuit indicating signal SP based on the voltage detecting signal Ct. The counting circuit 32 counts a number of times when a specific state of the voltage detecting signal Ct occurs. When the number of times reaches a set value, the short-circuit indicating signal SP indicates that the output terminal OUT of the asymmetrical half-bridge flyback converter 20 is short-circuited. The specific state of the voltage detecting signal Ct may include, but not limited to, a rising edge, a falling edge, a specific voltage level, a specific value of the voltage detecting signal Ct, or any indications of the drop of the auxiliary winding sampling voltage Va. For example, in one embodiment, the voltage detecting signal Ct is a signal having a high voltage level and a low voltage level. The voltage detecting signal Ct is at the low voltage level when the auxiliary winding sampling voltage Va is greater than the short-circuit reference voltage Vref1. The voltage detecting signal Ct transitions to the high voltage level when the auxiliary winding sampling voltage Va decreases to be less than the short-circuit reference voltage Vref1. In this embodiment, the counting circuit 32 counts the number of rising edges of the voltage detecting signal Ct. In one embodiment, when the number of rising edges of the voltage detecting signal Ct reaches the set value (e.g., 6), which means that the auxiliary winding sampling voltage Va is less than the short-circuit reference voltage Vref1 in 6 consecutive switching cycles, the counting circuit 32 provides the short-circuit indicating signal SP indicating the output terminal OUT is short-circuited.

In some embodiments, the first switch Q1 and the second switch Q2 are turned on and off alternately during operation. In order to avoid shoot through between the first switch Q1 and the second switch Q2, a dead time is applied between the turning off of the first switch Q1 and the turning on of the second switch Q2 (i.e., the first switch Q1 and the second switch Q2 are both off during the dead time). Similarly, there is the dead time between the turning off of the second switch Q2 and the turning on of the first switch Q1. It should be understood, the switching cycle of the asymmetrical half-bridge flyback converter 20 is defined by a period of time that the first switch Q1 or the second switch Q2 is turned on and turned off. For example, the switching cycle starts from the time when the first switch Q1 turns on to the next time it turns on again. For another example, the switching cycle starts from the time when the second switch Q2 turns on to the next time it turns on again. In another example, the switching cycle starts from the time when the first switch Q1 turns off to the next time it turns off again.

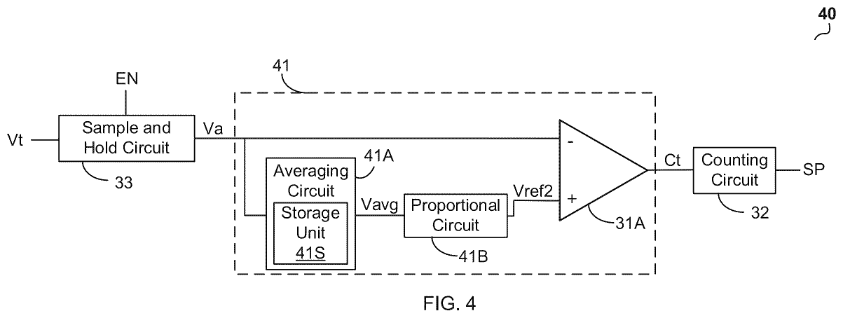

FIG. 4 shows a schematic diagram of a short-circuit indicating circuit 40 in accordance with an embodiment of the present invention. As shown in FIG. 4, the short-circuit indicating circuit 40 includes a voltage detecting circuit 41, the counting circuit 32 and the sample and hold circuit 33. The voltage detecting circuit 41 includes an averaging circuit 41A, a proportional circuit 41B and the comparison circuit 31A. The averaging circuit 41A is configured to receive the auxiliary winding sampling voltage Va, and to provide an auxiliary winding average voltage Vavg based on the auxiliary winding sampling voltage Va. The auxiliary winding average voltage Vavg indicates an average or a weighted average of the auxiliary winding sampling voltages Va during multiple switching cycles. In one embodiment, the averaging circuit 41A includes a storage unit 41S for storing the auxiliary winding sampling voltages Va during multiple switching cycles.

In one embodiment, the averaging circuit 41A is configured to calculate the average of the auxiliary winding sampling voltages Va during multiple switching cycles to obtain the auxiliary winding average voltage Vavg. The auxiliary winding average voltage Vavg could be expressed as: Vavg=(Va_n-5+Va_n-4+Va_n-3+Va_n-2+Va_n-1+Va_n)/6, where n is a natural number. Va_n represents the auxiliary winding sampling voltage Va of a current switching cycle. Va_n-5, Va_n-4, Va_n-3, Va_n-2, Va_n-1 represent the auxiliary winding sampling voltages Va of 5 switching cycles preceding the current switching cycle, respectively.

In one embodiment, the averaging circuit 41A is configured to calculate the weighted average of the auxiliary winding sampling voltages Va during multiple switching cycles to obtain the auxiliary winding average voltage Vavg. The auxiliary winding average voltage Vavg could be expressed as: Vavg=m1×Va_n-5+m2×Va_n-4+m3×Va_n-3+m4×Va_n-2+m5×Va_n-1+m6×Va_n. In some embodiments, m1-m5 are set to 0.1 and m6 is set to 0.5 to weight the auxiliary winding sampling voltage Va of the current switching cycle, thereby enhancing the effect of the auxiliary winding sampling voltage Va of the current switching cycle on the short circuit detection. Persons of ordinary skill in the art may determine values of m1-m6 according to the specific application. For example, when the sampling of the current switching cycle is probably abnormal, m1-m5 are set to 0.18 and m6 is set to 0.1 to reduce the weight of the auxiliary winding sampling voltage Va of the current switching cycle, thereby mitigating the effect of the auxiliary winding sampling voltage Va of the current switching cycle on the short-circuit detection.

The proportional circuit 41B is configured to receive the auxiliary winding average voltage Vavg, and to provide a short-circuit reference voltage Vref2 proportional to the auxiliary winding average voltage Vavg. In one embodiment, the short-circuit reference voltage Vref2 could be expressed as: Vref2=K1×Vavg, where the proportionality coefficient K1 is a constant value less than 1. Persons of ordinary skill in the art may set the proportionality coefficient K1 according to the requirements of the application. For instance, the proportionality coefficient K1 could be set based on the required short-circuit reference voltage Vref2 and the auxiliary winding sampling voltages Va. The short-circuit reference voltage Vref2 is set based on the auxiliary winding sampling voltages Va of the switching cycles of the asymmetrical half-bridge flyback converter 20 under normal operation. In one embodiment, the auxiliary winding sampling voltage Va is about 5V under normal operation, and a possible short circuit of the output terminal OUT is determined when the auxiliary winding sampling voltage Va is less than 3V. Thus, the proportionality coefficient K1 could be set to 0.6.

The comparison circuit 31A is configured to receive the auxiliary winding sampling voltage Va and the short-circuit reference voltage Vref2, and to provide the voltage detecting signal Ct based on the comparison result of the auxiliary winding sampling voltage Va and short-circuit reference voltage Vref2. The auxiliary winding sampling voltage Va received by the comparison circuit 31A is the auxiliary winding sampling voltage Va_n of the current switching cycle.

The counting circuit 32 is configured to receive the voltage detecting signal Ct, and to provide the short-circuit indicating signal SP based on the voltage detecting signal Ct. The counting circuit 32 counts the number of times when the specific state of the voltage detecting signal Ct occurs. When the number of times reaches the set value, the short-circuit indicating signal SP indicates that the output terminal OUT of the asymmetrical half-bridge flyback converter 20 is short-circuited. The specific state of the voltage detecting signal Ct may include, but not limited to, the rising edge, the falling edge, the specific voltage level, the specific value of the voltage detecting signal, or any indications of the drop of the auxiliary winding sampling voltage Va. For example, in one embodiment, the voltage detecting signal Ct is the signal having the high voltage level and the low voltage level. The voltage detecting signal Ct is at the low voltage level when the auxiliary winding sampling voltage Va is greater than the short-circuit reference voltage Vref2. The voltage detecting signal Ct transitions to the high voltage level when the auxiliary winding sampling voltage Va decreases to be less than the short-circuit reference voltage Vref2. In this embodiment, the counting circuit 32 counts the number of rising edges of the voltage detecting signal Ct. In one embodiment, when the number of rising edges of the voltage detecting signal Ct reaches the set value (e.g., 6), which means that the auxiliary winding sampling voltage Va is less than the short-circuit reference voltage Vref2 in 6 consecutive switching cycles, the counting circuit 32 provides the short-circuit indicating signal SP indicating the output terminal OUT is short-circuited.

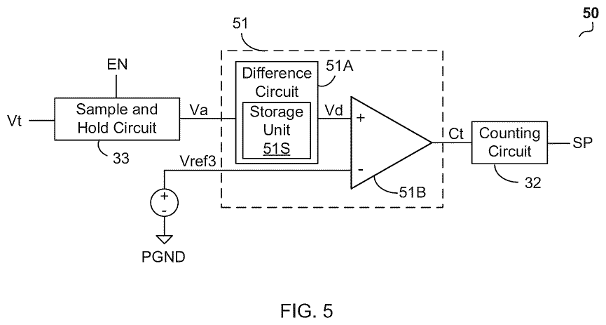

FIG. 5 shows a schematic diagram of a short-circuit indicating circuit 50 in accordance with an embodiment of the present invention. As shown in FIG. 5, the short-circuit indicating circuit 50 includes a voltage detecting circuit 51, the counting circuit 32 and the sample and hold circuit 33. The voltage detecting circuit 51 includes a difference circuit 51A and a comparison circuit 51B. The difference circuit 51A is configured to receive the auxiliary winding sampling voltage Va, and to provide a difference voltage Vd based on the auxiliary winding sampling voltage Va. The difference voltage Vd indicates a difference between the auxiliary winding sampling voltages Va of two adjacent switching cycles. In one embodiment, the difference circuit 51A includes a storage unit 51S. The difference circuit 51A is configured to receive the auxiliary winding sampling voltage Va, and to store the auxiliary winding sampling voltages Va of at least two switching cycles in the storage unit 51S. The difference circuit 51A is configured to perform a difference calculation on the auxiliary winding sampling voltages Va of the at least two switching cycles to obtain the difference voltage Vd. In one embodiment, the difference voltage Vd could be expressed as: Vd=Va_n-1-Va_n, where n is a natural number. Va_n represents the auxiliary winding sampling voltage Va of the current switching cycle. Va_n-1 represents the auxiliary winding sampling voltage Va of the adjacent previous switching cycle.

The comparison circuit 51B is configured to receive the difference voltage Vd and a difference reference voltage Vref3, and to provide the voltage detecting signal Ct based on the comparison result of the difference voltage Vd and the difference reference voltage Vref3. In the embodiment of FIG. 5, the difference reference voltage Vref3 is a constant value greater than the difference voltage Vd of the asymmetrical half-bridge flyback converter 20 under normal operation. In one embodiment, the difference reference voltage Vref3 could be provided by a voltage source. Person of ordinary skill in the art may set the difference reference voltage Vref3 based on the fluctuation of the auxiliary winding sampling voltage Va (corresponding to the fluctuation of the output voltage Vout) of the asymmetrical half-bridge flyback converter 20 under normal operation in the specific application. When the difference voltage Vd increases to the difference reference voltage Vref3, which means that the fluctuation of the output voltage Vout is large, in other words, the output terminal OUT may be short-circuited.

The counting circuit 32 is configured to receive the voltage detecting signal Ct, and to provide the short-circuit indicating signal SP based on the voltage detecting signal Ct. The counting circuit 32 counts the number of times when the specific state of the voltage detecting signal Ct occurs. When the number of times reaches the set value, the short-circuit indicating signal SP indicates that the output terminal OUT of the asymmetrical half-bridge flyback converter 20 is short-circuited. The specific state of the voltage detecting signal Ct may include, but not limited to, the rising edge, the falling edge, the specific voltage level, the specific value of the voltage detecting signal Ct, or any indications of the drop of the auxiliary winding sampling voltage Va. For example, in one embodiment, the voltage detecting signal Ct is the signal having the high voltage level and the low voltage level. The voltage detecting signal Ct is at the low voltage level when the difference voltage Vd is less than the difference reference voltage Vref3. The voltage detecting signal Ct transitions to the high voltage level when the difference voltage Vd increases to be greater than the difference reference voltage Vref3. In this embodiment, the counting circuit 32 counts the number of rising edges of the voltage detecting signal Ct. In one embodiment, when the number of rising edges of the voltage detecting signal Ct reaches the set value (e.g., 6), which means that the difference voltage Vd is greater than the difference reference voltage Vref3 in 6 consecutive switching cycles, the counting circuit 32 provides the short-circuit indicating signal SP indicating the output terminal OUT is short-circuited.

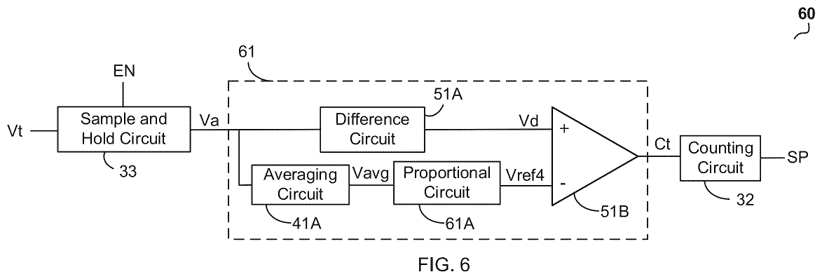

FIG. 6 shows a schematic diagram of a short-circuit indicating circuit 60 in accordance with an embodiment of the present invention. As shown in FIG. 6, the short-circuit indicating circuit 60 includes a voltage detecting circuit 61, the counting circuit 32 and the sample and hold circuit 33. The voltage detecting circuit 61 includes the difference circuit 51A, the averaging circuit 41A, a proportional circuit 61A and the comparison circuit 51B. The difference circuit 51A is configured to receive the auxiliary winding sampling voltage Va, and to provide the difference voltage Vd based on the auxiliary winding sampling voltage Va. The averaging circuit 41A is configured to receive the auxiliary winding sampling voltage Va, and to calculate the average of the auxiliary winding sampling voltages Va during multiple switching cycles to provide the auxiliary winding average voltage Vavg. The proportional circuit 61A is configured to receive the auxiliary winding average voltage Vavg, and to provide a difference reference voltage Vref4 proportional to the auxiliary winding average voltage Vavg. In one embodiment, the difference reference voltage Vref4 could be expressed as: Vref4=K2×Vavg, where the proportionality coefficient K2 is a constant value less than 1. Persons of ordinary skill in the art may set the proportionality coefficient K2 according to the requirements of the application. For instance, the proportionality coefficient K2 could be set based on the required difference reference voltage Vref4 and the auxiliary winding sampling voltages Va. The difference reference voltage Vref4 is set based on the difference between the auxiliary winding sampling voltages Va of the two adjacent switching cycles of the asymmetrical half-bridge flyback converter 20 under normal operation.

The comparison circuit 51B is configured to receive the difference voltage Vd and the difference reference voltage Vref4, and to provide the voltage detecting signal Ct based on the comparison result of the difference voltage Vd and the difference reference voltage Vref4. In the embodiment of FIG. 6, the difference reference voltage Vref4 is proportional to the average or weighted average of the auxiliary winding sampling voltage Va (i.e., the auxiliary winding average voltage Vavg) during multiple switching cycles. Therefore, the short circuit of the output terminal OUT could be determined more accurately through using the adaptive reference voltage Vref4.

The counting circuit 32 is configured to receive the voltage detecting signal Ct, and to provide the short-circuit indicating signal SP based on the voltage detecting signal Ct. The counting circuit 32 is configured to count the number of times when the specific state of the voltage detecting signal Ct occurs. When the number of times reaches the set value, the short-circuit indicating signal SP indicates that the output terminal OUT of the asymmetrical half-bridge flyback converter 20 is short-circuited. The specific state of the voltage detecting signal Ct may include, but not limited to, the rising edge, the falling edge, the specific voltage level, the specific value of the voltage detecting signal, or any indications of the drop of the auxiliary winding sampling voltage Va. For example, in one embodiment, the voltage detecting signal Ct is the signal having the high voltage level and the low voltage level. The voltage detecting signal Ct is at the low voltage level when the difference voltage Vd is less than the difference reference voltage Vref4. The voltage detecting signal Ct transitions to the high voltage level when the difference voltage Vd increases to be greater than the difference reference voltage Vref4. In this embodiment, the counting circuit 32 counts the number of rising edges of the voltage detecting signal Ct. In one embodiment, when the number of rising edges of the voltage detecting signal Ct reaches the set value (e.g., 6), which means that the difference voltage Vd is greater than the difference reference voltage Vref4 in 6 consecutive switching cycles, the counting circuit 32 provides the short-circuit indicating signal SP indicating the output terminal OUT is short-circuited.

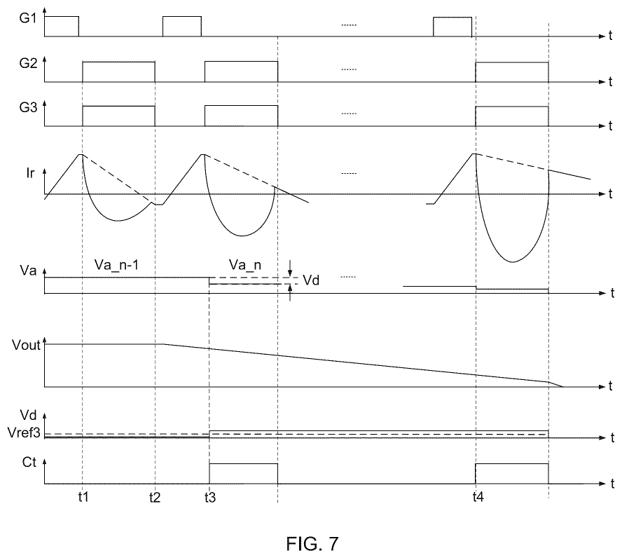

FIG. 7 shows working waveforms of the asymmetrical half-bridge flyback converter 20 employing the short-circuit indicating circuit 50 in accordance with an embodiment of the present invention. As shown in FIG. 7, the first control signal G1 and the second control signal G2 are interleaved so the first switch Q1 and the second switch Q2 are turned on alternately. The working principle of the control circuit of the present invention is described below with reference to FIGS. 2, 5 and 7.

As shown in FIG. 7, at time t1, the switch Q3 is turned on, and the auxiliary winding sampling voltage Va is updated and maintained. During time t1-t2, the output voltage Vout remains unchanged, the output terminal OUT is not short-circuited. Therefore, the difference voltage Vd (i.e., the difference between the auxiliary winding sampling voltages Va of the two adjacent switching cycles, which indicates the fluctuation of the output voltage Vout) is less than the difference reference voltage Vref3. The voltage detecting signal Ct provided by the comparison circuit 51B is at the low voltage level and does not transition.

At time t2, the switch Q3 is turned off, the auxiliary winding sampling voltage Va follows the auxiliary winding voltage Vt, the difference voltage Vd remains unchanged till time t3.

At time t3, the switch Q3 is turned on again. Due to the output terminal OUT is short-circuited, the output voltage Vout drops. The auxiliary winding voltage Vt follows the output voltage Vout, thus the auxiliary winding sampling voltage Va obtained by sampling the auxiliary winding voltage Vt decreases to be less than the auxiliary winding sampling voltage Va of the previous switching cycle. Thereby, the difference voltage Vd (i.e., Vd=Va_n-1-Va_n) increases to be greater than the difference reference voltage Vref3. When the difference voltage Vd increases to the difference reference voltage Vref3, the voltage detecting signal Ct provided by the comparison circuit 51B transitions to the high voltage level. The voltage detecting signal Ct is provided to the counting circuit 32. In some embodiments, the counting circuit 32 counts the number of times when the voltage detecting signal Ct transitions to the high voltage level from the low voltage level. For example, the counting circuit 32 counts the number of the rising edge of the voltage detecting signal Ct.

At time t4, the voltage detecting signal Ct transitions to the high voltage level from the low voltage level again. When the number of times when the voltage detecting signal Ct transitions to the high voltage level from the low voltage level reaches the set value (e.g., 6), which means that large drops of the output voltage Vout are detected in the 6 consecutive switching cycles, the output terminal OUT is determined to be short-circuited. In this case, the short-circuit processing circuit 21B turns off the first switch Q1 and the second switch Q2 to stop the operation of the asymmetrical half-bridge flyback converter 20, thereby preventing devices in the circuit from being damaged by the short-circuit of output terminal OUT. In the embodiment of FIG. 7, after time t4, the first switch Q1 keeps off, and the second switch Q2 keeps off after the on-time of the second switch Q2 is finished. Persons skilled in the art could reset the voltage detecting signal Ct in accordance with the requirements of the application. For example, the voltage detecting signal Ct could be reset based on the falling edge of the second control signal G2.

In the embodiments of the present invention, the working principle of the control circuit is described with reference to the asymmetrical half-bridge flyback converter. It should be appreciated that the control circuit of the present invention is applicable to other isolated switching circuits, e.g., conventional flyback circuit and LLC circuit.

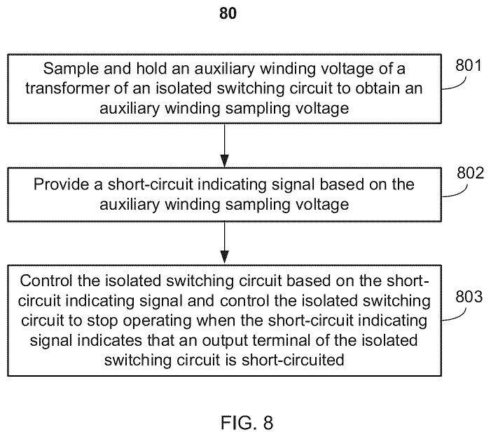

FIG. 8 shows a flow diagram of a method 80 for controlling an isolated switching circuit in accordance with an embodiment of the present invention. The isolated switching circuit includes an isolated device. In one embodiment, the isolated device is a transformer. The primary side circuit and the secondary side circuit of the isolated switching circuit are isolated by the isolated device. The primary side circuit includes at least one switch. Through turning on and off the at least one switch, the isolated switching circuit transfers energy from the primary side circuit to the secondary side circuit to power a load. The method 80 includes steps 801-803.

At step 801, an auxiliary winding voltage of the transformer of the isolated switching circuit is sampled and held to obtain an auxiliary winding sampling voltage.

At step 802, a short-circuit indicating signal is provided based on the auxiliary winding sampling voltage.

At step 803, the isolated switching circuit is controlled based on the short-circuit indicating signal, and the isolated switching circuit is controlled to stop operating when the short-circuit indicating signal indicates that an output terminal of the isolated switching circuit is short-circuited.

When the primary winding of the transformer of the isolated switching circuit transfers the energy to the secondary winding, the auxiliary winding voltage is associated with an output voltage of the isolated switching circuit. In one embodiment, in each switching cycle, when the primary winding of the transformer of the isolated switching circuit transfers energy to the secondary winding (i.e., a secondary switch of the isolated switching circuit is on), the auxiliary winding voltage is sampled and held to obtain the auxiliary winding sampling voltage.

In one embodiment, the step 802 includes the following steps. A voltage detecting signal is provided based on the auxiliary winding sampling voltage and a short-circuit reference voltage. A number of times when the voltage detecting signal indicates that the auxiliary winding sampling voltage is less than the short-circuit reference voltage is counted. The short-circuit indicating signal is provided to indicate that the output terminal of the isolated switching circuit is short-circuited when the number of times reaches a set value. The set value could be set according to requirements of the specific application.

In one embodiment, the short-circuit reference voltage is a constant value, which is less than the auxiliary winding sampling voltage of the isolated switching circuit under normal operation.

In one embodiment, the short-circuit reference voltage is proportional to an average or a weighted average of auxiliary winding sampling voltages during multiple consecutive switching cycles.

In one embodiment, the step 802 includes the following steps. A difference voltage is provided based on a difference between auxiliary winding sampling voltages of two adjacent switching cycles. The voltage detecting signal is provided based on the difference voltage and a difference reference voltage. A number of times when the voltage detecting signal indicates that the difference voltage is greater than the difference reference voltage is counted. The short-circuit indicating signal is provided to indicate that the output terminal of the isolated switching circuit is short-circuited when the number of times reaches the set value.

In one embodiment, the difference reference voltage is a constant value, which is greater than the difference between the auxiliary winding sampling voltages of two adjacent switching cycles of the isolated switching circuit under normal operation.

In one embodiment, the difference reference voltage is proportional to the average or the weighted average of the auxiliary winding sampling voltages during multiple consecutive switching cycles.

It should be understood, the circuit and the workflow described in the present invention are just for schematic illustration. Any circuit can realize the function and operation of the present invention does not depart from the spirit and the scope of the invention.

While specific embodiments of the present invention have been provided, it is to be understood that these embodiments are for illustration purposes and not limiting. Since the invention can be practiced in various forms without distracting the spirit or the substance of the invention. It should be appreciated that the above embodiments are not confined to any aforementioned specific detail but should be explanatory broadly within the spirit and scope limited by the appended claims. Thus, all the variations and modification falling into the scope of the claims and their equivalents should be covered by the appended claims.

What is claimed is:

1. A control circuit for an asymmetrical half-bridge flyback converter, comprising:
a short-circuit indicating circuit configured to receive an auxiliary winding voltage of a transformer of the asymmetrical half-bridge flyback converter, and to provide a short-circuit indicating signal based on the auxiliary winding voltage; and
a short-circuit processing circuit configured to receive the short-circuit indicating signal, and to provide at least one short-circuit control signal to control the asymmetrical half-bridge flyback converter based on the short-circuit indicating signal, wherein the short-circuit control signal is configured to control the asymmetrical half-bridge flyback converter to stop operating when the short-circuit indicating signal indicates that an output terminal of the asymmetrical half-bridge flyback converter is short-circuited.

2. The control circuit of claim 1, wherein the short-circuit indicating circuit comprises:
a voltage detecting circuit configured to receive an auxiliary winding sampling voltage, and to provide a voltage detecting signal based on the auxiliary winding sampling voltage, wherein the auxiliary winding sampling voltage is provided based on the auxiliary winding voltage; and
a counting circuit configured to receive the voltage detecting signal, and to provide the short-circuit indicating signal based on the voltage detecting signal.

3. The control circuit of claim 2, wherein the voltage detecting circuit comprises:
a comparison circuit configured to receive the auxiliary winding sampling voltage and a short-circuit reference voltage, and to provide the voltage detecting signal based on the auxiliary winding sampling voltage and the short-circuit reference voltage; and wherein
the counting circuit is configured to count a number of times when the voltage detecting signal indicates that the auxiliary winding sampling voltage is less than the short-circuit reference voltage, and the short-circuit indicating signal indicates that the output terminal of the asymmetrical half-bridge flyback converter is short-circuited when the number of times reaches a set value.

4. The control circuit of claim 3, wherein the voltage detecting circuit further comprises:
an averaging circuit configured to receive the auxiliary winding sampling voltage, and to provide an auxiliary winding average voltage based on auxiliary winding sampling voltages during multiple switching cycles; and
a proportional circuit configured to provide the short-circuit reference voltage proportional to the auxiliary winding average voltage based on the auxiliary winding average voltage.

5. The control circuit of claim 2, wherein the voltage detecting circuit comprises:
a difference circuit configured to receive the auxiliary winding sampling voltage, and to provide a difference voltage based on a difference between auxiliary winding sampling voltages of two adjacent switching cycles; and
a comparison circuit configured to receive the difference voltage and a difference reference voltage, and to provide the voltage detecting signal based on the difference voltage and the difference reference voltage; and wherein
the counting circuit is configured to count a number of times when the voltage detecting signal indicates that the difference voltage is greater than the difference reference voltage, and the short-circuit indicating signal indicates that the output terminal of the asymmetrical half-bridge flyback converter is short-circuited when the number of times reaches a set value.

6. The control circuit of claim 5, wherein the voltage detecting circuit further comprises:
an averaging circuit configured to receive the auxiliary winding sampling voltage, and to provide an auxiliary winding average voltage based on auxiliary winding sampling voltages during multiple switching cycles; and
a proportional circuit configured to provide the difference reference voltage proportional to the auxiliary winding average voltage based on the auxiliary winding average voltage.

7. The control circuit of claim 2, wherein the short-circuit indicating circuit further comprises:
a sample and hold circuit configured to be coupled to an auxiliary winding of the transformer to receive the auxiliary winding voltage, and to provide the auxiliary winding sampling voltage based on the auxiliary winding voltage, wherein the auxiliary winding sampling voltage is obtained by sampling and holding the auxiliary winding voltage during a time period when a secondary switch of the asymmetrical half-bridge flyback converter is on.

8. An asymmetrical half-bridge flyback converter, comprising:
a first switch;
a second switch coupled in series with the first switch between an input terminal of the asymmetrical half-bridge flyback converter and a primary side reference ground;
a transformer having a primary winding, a secondary winding and an auxiliary winding, wherein the primary winding is coupled to a switching terminal between the first switch and the second switch;
a resonant capacitor coupled in series with the primary winding of the transformer; and
a control circuit, comprising:
a short-circuit indicating circuit configured to receive an auxiliary winding voltage of the transformer, and to provide a short-circuit indicating signal based on the auxiliary winding voltage; and
a short-circuit processing circuit configured to receive the short-circuit indicating signal, and to provide a first short-circuit control signal and a second short-circuit control signal based on the short-circuit indicating signal to control the first switch and the second switch respectively, wherein the first switch and the second switch are turned off when the short-circuit indicating signal indicates that an output terminal of the asymmetrical half-bridge flyback converter is short-circuited.

9. The asymmetrical half-bridge flyback converter of claim 8, wherein the short-circuit indicating circuit comprises:
a voltage detecting circuit configured to receive an auxiliary winding sampling voltage, and to provide a voltage detecting signal based on the auxiliary winding sampling voltage, wherein the auxiliary winding sampling voltage is provided based on the auxiliary winding voltage; and
a counting circuit configured to receive the voltage detecting signal, and to provide the short-circuit indicating signal based on the voltage detecting signal.

10. The asymmetrical half-bridge flyback converter of claim 9, wherein the voltage detecting circuit comprises:
a comparison circuit configured to receive the auxiliary winding sampling voltage and a short-circuit reference voltage, and to provide the voltage detecting signal based on the auxiliary winding sampling voltage and the short-circuit reference voltage; and wherein
the counting circuit is configured to count a number of times when the voltage detecting signal indicates that the auxiliary winding sampling voltage is less than the short-circuit reference voltage, and the short-circuit indicating signal indicates that the output terminal of the asymmetrical half-bridge flyback converter is short-circuited when the number of times reaches a set value.

11. The asymmetrical half-bridge flyback converter of claim 10, wherein the voltage detecting circuit further comprises:
an averaging circuit configured to receive the auxiliary winding sampling voltage, and to provide an auxiliary winding average voltage based on auxiliary winding sampling voltages during multiple switching cycles; and
a proportional circuit configured to provide the short-circuit reference voltage proportional to the auxiliary winding average voltage based on the auxiliary winding average voltage.

12. The asymmetrical half-bridge flyback converter of claim 9, wherein the voltage detecting circuit comprises:
a difference circuit configured to receive the auxiliary winding sampling voltage, and to provide a difference voltage based on a difference between auxiliary winding sampling voltages of two adjacent switching cycles; and
a comparison circuit configured to receive the difference voltage and a difference reference voltage, and to provide the voltage detecting signal based on the difference voltage and the difference reference voltage; and wherein
the counting circuit is configured to count a number of times when the voltage detecting signal indicates that the difference voltage is greater than the difference reference voltage, and the short-circuit indicating signal indicates that the output terminal of the asymmetrical half-bridge flyback converter is short-circuited when the number of times reaches a set value.

13. The asymmetrical half-bridge flyback converter of claim 12, wherein the voltage detecting circuit further comprises:
an averaging circuit configured to receive the auxiliary winding sampling voltage, and to provide an auxiliary winding average voltage based on auxiliary winding sampling voltages during multiple switching cycles; and
a proportional circuit configured to provide the difference reference voltage proportional to the auxiliary winding average voltage based on the auxiliary winding average voltage.

14. The asymmetrical half-bridge flyback converter of claim 9, wherein the short-circuit indicating circuit further comprises:
a sample and hold circuit configured to be coupled to the auxiliary winding of the transformer to receive the auxiliary winding voltage, and to provide the auxiliary winding sampling voltage based on the auxiliary winding voltage, wherein the auxiliary winding sampling voltage is obtained by sampling and holding the auxiliary winding voltage during a time period when a secondary switch of the asymmetrical half-bridge flyback converter is on.

15. A method for controlling an isolated switching circuit, comprising:
sampling and holding an auxiliary winding voltage of a transformer of the isolated switching circuit to obtain an auxiliary winding sampling voltage;
providing a short-circuit indicating signal based on the auxiliary winding sampling voltage; and
controlling the isolated switching circuit based on the short-circuit indicating signal, and controlling the isolated switching circuit to stop operating when the short-circuit indicating signal indicates that an output terminal of the isolated switching circuit is short-circuited.

16. The method of claim 15, wherein the step of providing the short-circuit indicating signal based on the auxiliary winding sampling voltage comprises:
providing a voltage detecting signal based on the auxiliary winding sampling voltage and a short-circuit reference voltage; and
counting a number of times when the voltage detecting signal indicates that the auxiliary winding sampling voltage is less than the short-circuit reference voltage, and providing the short-circuit indicating signal to indicate that the output terminal of the isolated switching circuit is short-circuited when the number of times reaches a set value.

17. The method of claim 16, wherein the short-circuit reference voltage is proportional to an average or a weighted average of auxiliary winding sampling voltages during multiple consecutive switching cycles.

18. The method of claim 15, wherein the step of providing the short-circuit indicating signal based on the auxiliary winding sampling voltage comprises:
providing a difference voltage based on a difference between auxiliary winding sampling voltages of two adjacent switching cycles;
providing a voltage detecting signal based on the difference voltage and a difference reference voltage; and
counting a number of times when the voltage detecting signal indicates that the difference voltage is greater than the difference reference voltage, and providing the short-circuit indicating signal to indicate that the output terminal of the isolated switching circuit is short-circuited when the number of times reaches a set value.

19. The method of claim 18, wherein the difference reference voltage is a constant value.

20. The method of claim 18, wherein the difference reference voltage is proportional to an average or a weighted average of auxiliary winding sampling voltages during multiple consecutive switching cycles.
